(19) United States
(12) Patent Application Publication
(10) Pub. No.: US 2025/0366035 A1
(43) Pub. Date: Nov. 27, 2025

(54) INTEGRATED CIRCUIT DEVICE AND METHOD FOR FABRICATING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/670,133

(22) Filed: May 21, 2024

(51) Int. Cl. H01L 29/417; H01L 23/528; H01L 29/06; H01L 29/40; H01L 29/423; H01L 29/66; H01L 29/775

(52) U.S. Cl. CPC H10D 30/6729; H01L 23/5286; H10D 30/014; H10D 30/43; H10D 30/6735; H10D 62/121; H10D 64/01; H10D 64/017

(57) ABSTRACT

An integrated circuit (IC) structure includes a channel region, a gate structure, an isolation structure, a source/drain epitaxial structure, and a backside source/drain contact. The channel region extends along a first direction. The gate structure is over the channel region. The gate structure and the isolation structure extend along a second direction different from the first direction and spaced apart from each other. The source/drain epitaxial structure is between the gate structure and the isolation structure. The backside source/drain contact is on a backside of the source/drain epitaxial structure. A space between the backside source/drain contact and the isolation structure is less than a space between the backside source/drain contact and the first gate structure in a first top view.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 illustrate layouts and cross-sectional views of an integrated circuit structure at intermediate stages of fabrication process according to some embodiments of the present disclosure.

FIG. 12 is a cross-sectional view of an integrated circuit structure according to some embodiments of the present disclosure.

FIGS. 13A and 13B illustrate layouts of an integrated circuit structure according to some embodiments of the present disclosure.

FIG. 13C illustrates a cross-sectional view taken along line X-X in FIGS. 13A and 13B.

FIG. 14 is a cross-sectional view of an integrated circuit structure according to some embodiments of the present disclosure.

FIGS. 15A and 15B illustrate layouts of an integrated circuit structure according to some embodiments of the present disclosure.

FIG. 15C illustrates a cross-sectional view taken along line X-X in FIGS. 15A and 15B.

FIG. 16 is a cross-sectional view of an integrated circuit structure according to some embodiments of the present disclosure.

FIGS. 17A and 17B illustrate layouts of an integrated circuit structure according to some embodiments of the present disclosure.

FIG. 17C illustrates a cross-sectional view taken along line X-X in FIGS. 17A and 17B.

FIG. 18 is a cross-sectional view of an integrated circuit structure according to some embodiments of the present disclosure.

FIGS. 19A and 19B illustrate layouts of an integrated circuit structure according to some embodiments of the present disclosure.

FIG. 19C illustrates a cross-sectional view taken along line X-X in FIGS. 19A and 19B.

FIG. 20 is a cross-sectional view of an integrated circuit structure according to some embodiments of the present disclosure.

FIGS. 21A and 21B illustrate layouts of an integrated circuit structure according to some embodiments of the present disclosure.

FIG. 21C illustrates a cross-sectional view taken along line X-X in FIGS. 21A and 21B.

FIG. 22 is a cross-sectional view of an integrated circuit structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

It is also noted that the present disclosure presents embodiments in the form of multi-gate transistors. Multi-gate transistors include those transistors whose gate structures are formed on at least two-sides of a channel region. Presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. In various embodiments, the devices can be planar transistor, fin field-effect transistor (FinFET), forksheet transistors, or complementary FET (CFET).

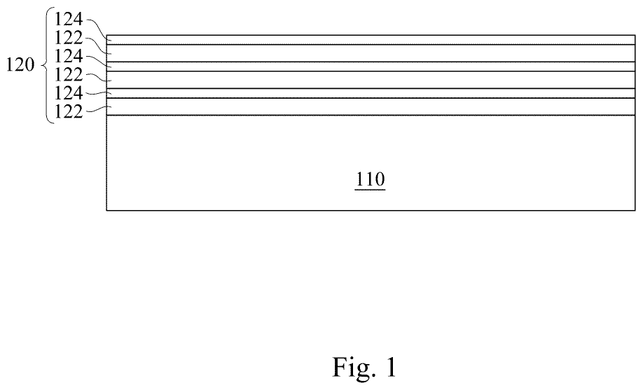

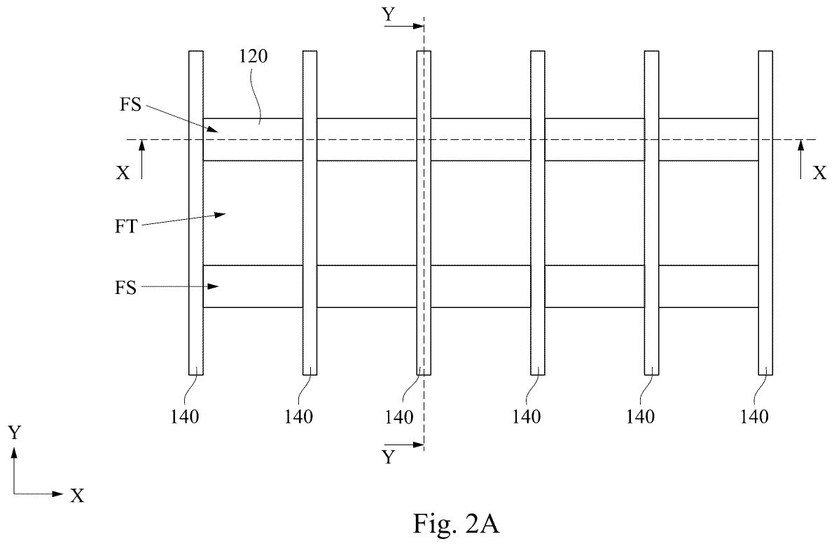

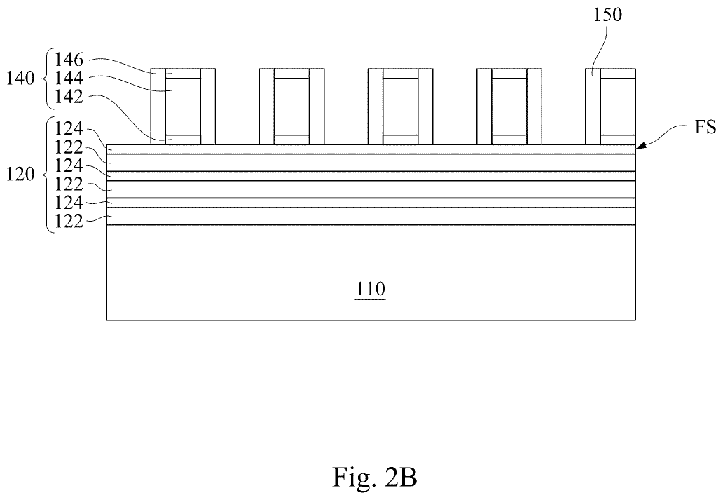

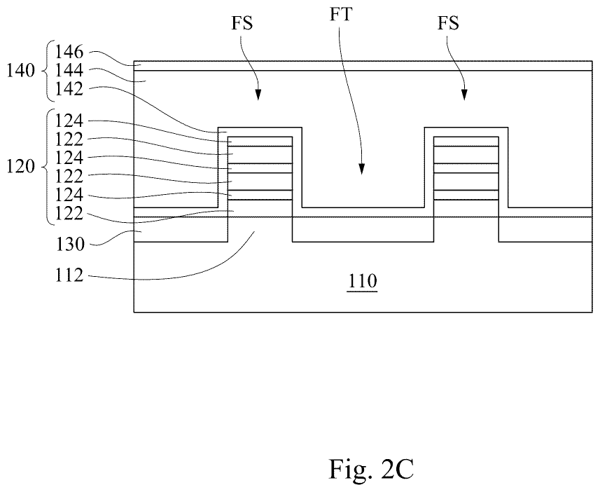

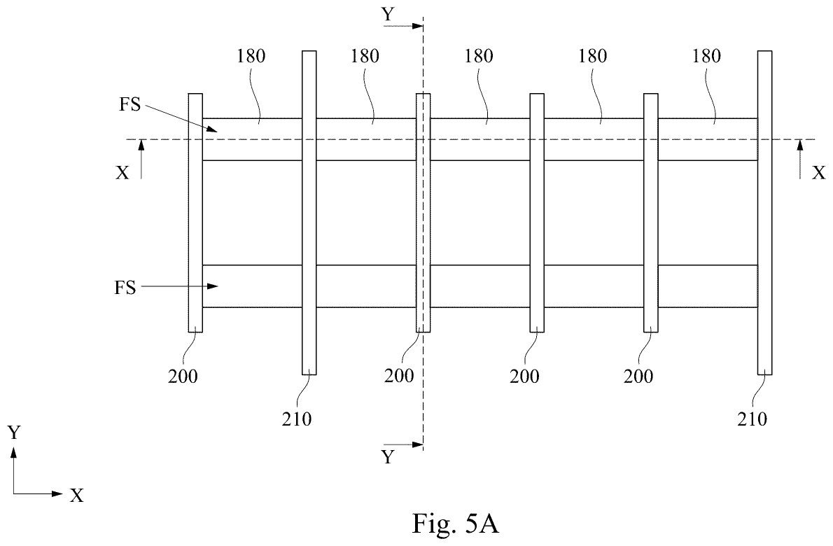

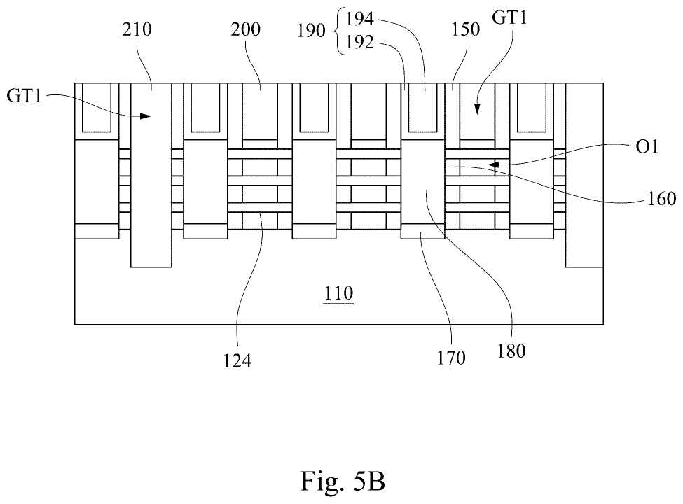

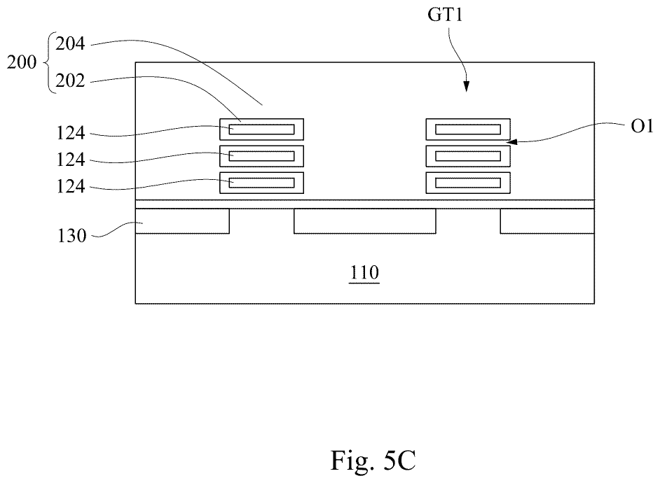

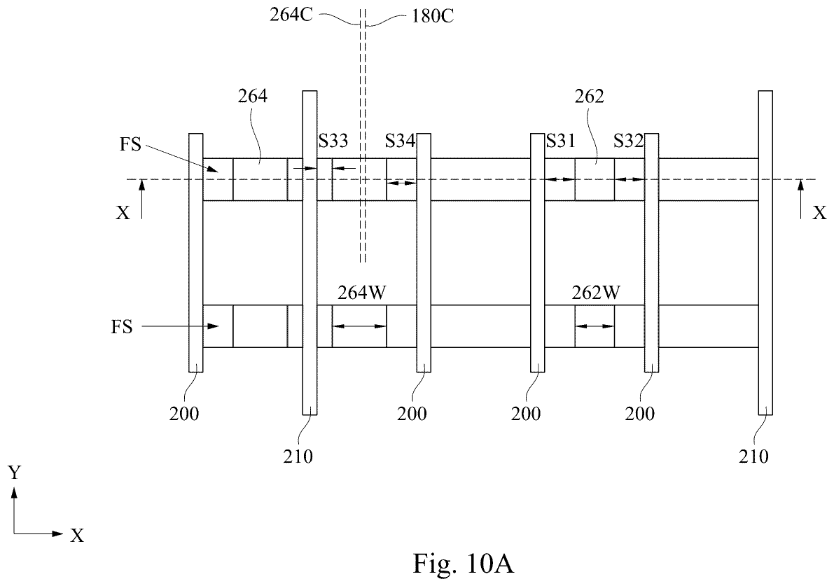

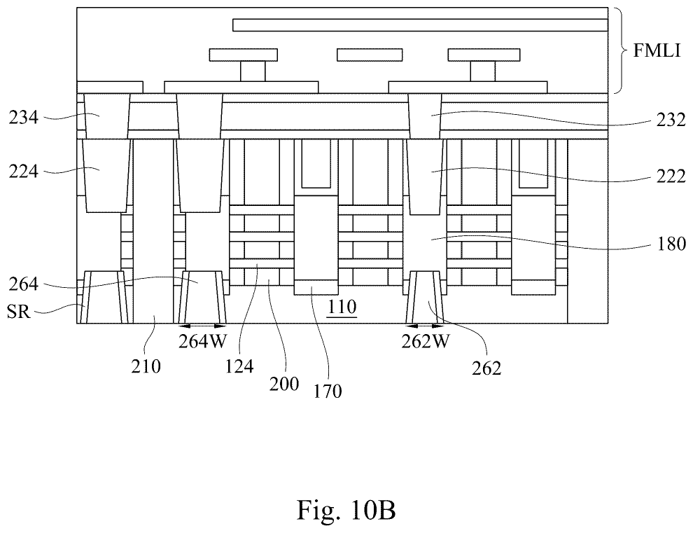

FIGS. 1-11 illustrate layouts and cross-sectional views of an integrated circuit structure at intermediate stages of fabrication process according to some embodiments of the present disclosure. FIGS. 2A, 5A, 7A, and 10A are layouts of the integrated circuit structure at the intermediate stages of fabrication process according to some embodiments of the present disclosure. FIGS. 2A, 5A, 6A, and 7A show front-side layouts, and FIG. 10A shows a back-side layout, while all the front-side layouts and back-side layouts are illustrated as being viewed from top/front side. FIGS. 2B, 3, 4, 5B, 6B, 7B, 9A, and 10B illustrate cross-sectional views taken along a fin direction X (e.g., the line X-X in FIGS. 2A, 5A, 6A, 7A, and 10A). FIGS. 2C, 5C, and 9B illustrate cross-sectional views taken along a gate direction Y (e.g., the line Y-Y in FIGS. 2A and 5A).

FIG. 1 shows an initial structure. The initial structure includes a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 110 may include a semiconductor-on-insulator (SOI) structure. For example, the substrate 110 may include a bulk semiconductor substrate, a buried dielectric layer over the bulk substrate, and a semiconductor layer over the buried dielectric layer.

An epitaxial stack 120 is formed over the substrate 110. The epitaxial stack 120 includes epitaxial layers 122 of a first composition interposed by epitaxial layers 124 of a second composition. The first and second compositions can be different. In some embodiments, the epitaxial layers 122 are SiGe and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below. It is noted that three layers of the epitaxial layers 122 and three layers of the epitaxial layers 124 are alternately arranged as illustrated in FIG. 1. It can be appreciated that any number of epitaxial layers can be formed in the epitaxial stack 120; the number of layers depending on the desired number of channels regions for the transistor. In some embodiments, the number of epitaxial layers 124 is between 2 and 10.

In some embodiments, the epitaxial layers 122 may be substantially uniform in thickness, and the epitaxial layers 124 of the stack are substantially uniform in thickness. As described in more detail below, the epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers or channel regions.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A-2C. The epitaxial stack 120 and the substrate 110 are patterned, thereby forming plural fins FS. The fins FS may extend along direction X. The patterning may include suitable lithography process and etching processes. The lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., reactive ion etching), wet etching, and/or other etching methods. In some embodiments, masks are formed over the epitaxial stack 120 by the photolithography process. The masks are used to protect regions of the substrate 110 and the epitaxial stack 120, while etching processes form trenches FT in unprotected regions through the epitaxial stack 120 and into the substrate 110, thereby leaving the plurality of extending fins FS.

In some alternative embodiments, the fins FS may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

Numerous other embodiments of methods to form the fins on the substrate may also be used including, for example, defining the fin region (e.g., by mask or isolation regions) and epitaxially growing the epitaxial stack 120 in the form of the fins FS. In various embodiments, each of the fins FS includes a base portion 112 patterned from the semiconductor substrate 110 and portions of each of the epitaxial layers 122 and 124 of the epitaxial stack 120.

Isolation structures 130 are formed in the trenches FT between the fins FS. The isolation structures 130 may be referred to as shallow trench isolation (STI) structures. By way of example and not limitation, a dielectric layer is first deposited over the substrate 110, filling the trenches FT with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, after deposition of the dielectric layer, the deposited dielectric material is thinned and planarized, for example by a chemical mechanical polishing (CMP) process.

In the layouts, regions between the isolation structures 130 are indicated as oxide-defined (OD) regions, which correspond to the fins FS. The isolation (or STI) structures 130 are recessed in an etch back process, such that the OD regions (e.g., fins FS) has exposed sidewall extending above the isolation structure STI. In some embodiments, the recessing process may include a dry etching process, a wet etching process, and/or a combination thereof. In some embodiments, a recessing depth is controlled (e.g., by controlling an etching time) so as to result in a target height of the exposed upper portion of the fins FS. The target height may expose sidewalls of the OD regions (e.g., fins FS). In the illustrated embodiments, the target height exposes each of the epitaxial layers 122 and 124 of the epitaxial stack 120 in the fins FS.

A dummy gate dielectric layer 142 is then conformally deposited in the trenches FT and over the isolation structures 130. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structures).

Dummy gate structures 140 are formed in accordance with some embodiments of the present disclosure. The dummy gate structures 140 may extend along the direction Y intersecting the direction X that the fins FS extend along. For example, the direction Y is orthogonal to the direction X. In some embodiments, the dummy gate structures 140 each include the dummy gate dielectric layer 142, a dummy gate electrode layer 144 and a hard mask 146. In some embodiments, the dummy gate structures 260 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

In some embodiments, the dummy gate electrode layer 144 may include polycrystalline silicon (polysilicon). In some embodiments, the hard mask 146 includes an oxide layer such as a pad oxide layer that may include SiO₂, and a nitride layer such as a pad nitride layer that may include Si₃N₄ and/or silicon oxynitride. In some embodiments, after patterning the dummy gate electrode layer 144, exposed portions of the dummy gate dielectric layer 142 not covered under the patterned dummy gate electrode layer 144 are removed from source/drain regions of the fins FS. The etch process may include a wet etch, a dry etch, and/or a combination thereof. The etch process is chosen to selectively etch the dummy gate dielectric layer 142 without substantially etching the fins FS, the dummy gate electrode layer 144 and the hard mask 146.

In some embodiments, gate spacers 150 are formed on sidewalls of the dummy gate structures 140. The gate spacers 150 may include a dielectric material such as SiO₂, Si₃N₄, carbon doped oxide, nitrogen doped oxide, porous oxide, or the combination thereof. The gate spacers 150 may include multiple dielectric materials. In some embodiments, the gate spacers 150 may further include air gaps. In some embodiments of formation of the gate spacers 150, a spacer material layer is first deposited over the substrate 110. The spacer material layer may be a conformal layer that is subsequently etched to form gate sidewall spacers on sidewalls of the dummy gate structures 140. In the illustrated embodiments, a spacer material layer is disposed conformally on top and sidewalls of the dummy gate structures 260. By way of example, the spacer material layer may be formed by depositing a dielectric material over the gate structures 140 using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins FS not covered by the dummy gate structures 140 (e.g., in source/drain regions of the fins FS denoted as “S” and “D”). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity. The gate spacers 150 serve to isolate metal gates from source contacts formed in subsequent processing.

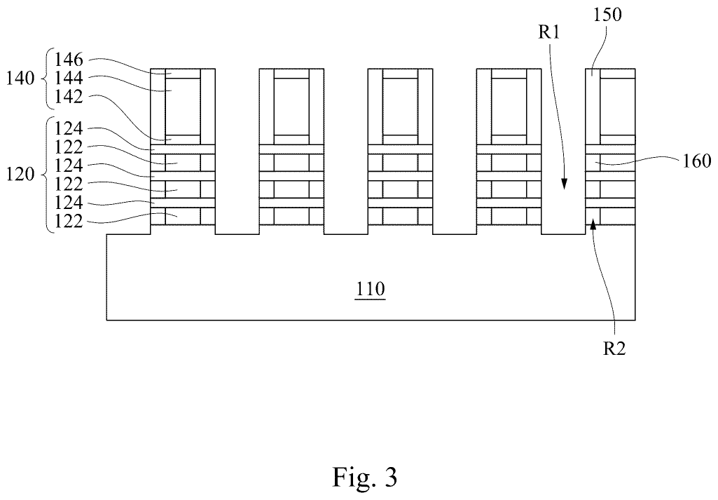

Reference is made to FIG. 3. Exposed portions of the semiconductor fins FS that extend laterally beyond the gate spacers 150 (e.g., in source/drain regions S/D of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. In some embodiments, the recesses R1 extends through the channel regions to the substrate 110 for exposing end surfaces of the sacrificial layers 122 and channel layers 124. In some embodiments, the anisotropic etching may be performed by a dry chemical etch with a plasma source and a reaction gas. The plasma source may be an inductively coupled plasma (ICR) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The sacrificial layers 122 may be laterally or horizontally recessed by using suitable etch techniques, resulting in lateral recesses R2 each vertically between corresponding channel layers 124. This step may be performed by using a selective etching process. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the channel layers 124 remain substantially intact during laterally recessing the sacrificial layers 122. As a result, the channel layers 124 laterally extend past opposite end surfaces of the sacrificial layers 122.

After the sacrificial layers 122 have been laterally recessed, inner spacers 160 are formed in the recesses R2 left by the lateral etching of the sacrificial layers 122. The inner spacers 160 may have a higher k value (or dielectric constant) than that of the gate spacers. For example, the inner spacers 160 includes a suitable dielectric material, such as SiO₂, Si₃N₄, SiON, SiOC, SiOCN, the like, or the combination thereof. In some embodiments, the inner spacers 160 may further include air gaps. Formation of the inner spacers 160 may include depositing an inner spacer material layer is formed to fill the recesses R2. The inner spacer material layer may be deposited by a suitable deposition method, such as ALD. After the deposition of the inner spacer material layer, an anisotropic etching process may be performed to trim the deposited inner spacer material, such that only portions of the deposited inner spacer material that fill the recesses left by the lateral etching of the sacrificial layers 122 are left. After the trimming process, the remaining portions of the deposited inner spacer material are denoted as inner spacers 160. The inner spacers 160 serve to isolate metal gates from source/drain epitaxial structures formed in subsequent processing.

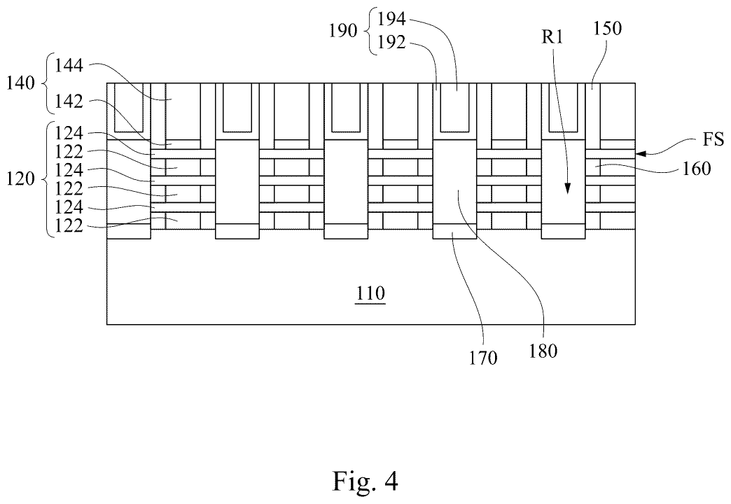

Reference is made to FIG. 4. Source/drain epitaxial structures 180 are formed in the recesses R1 in the fins FS. The source/drain epitaxial structures 180 may be formed by performing an epitaxial growth process that provides an epitaxial material on the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 124.

The source/drain epitaxial structures 180 may be in-situ doped during the epitaxial process by introducing doping species including: p-type dopants, such as boron; n-type dopants, such as phosphorus or arsenic; and/or other suitable dopants including combinations thereof. If the source/drain epitaxial structures 180 are not in-situ doped, an implantation process (i.e., a junction implant process) is performed to dope the source/drain epitaxial structures 180. In some exemplary embodiments, the source/drain epitaxial structures 180 in an NFET device include SiP, SiC, SiPC, SiAs, Si, or combination thereof. The n-type doping concentration of the source/drain epitaxial structures 180 (e.g., phosphorus, arsenic, or both) in the NFET device may be in a range from about 2E19/cm³ to about 3E21/cm³. In some exemplary embodiments, the source/drain epitaxial structures 180 in a PFET device include SiGe doped with boron, or SiGeC doped with boron, Ge doped with boron, Si doped with boron, or combination. The p-type doping concentration of the source/drain epitaxial structures 180 (e.g., boron) in the PFET device may be in a range from about 1E19/cm³ to about 6E20/cm³.

In some embodiments, prior to the formation of the source/drain epitaxial structures 180, and dielectric isolation layers 170 may be optionally formed at bottoms of the recesses R1. The dielectric isolation layers 170 may include a silicon nitride layer, silicon oxide layer, a silicon oxynitride layer, and/or other suitable materials. With the dielectric isolation layer 170, a bottom surface of the source/drain epitaxial structures 180 is between a top surface of the substrate 110 and a bottom surface of a bottommost one of the channel layers 124.

After the formation of the source/drain epitaxial structures 180, a dielectric material 190 is formed over the substrate 110 and filling the space between the dummy gate structures 140. In some embodiments, the dielectric material 190 includes a contact etch stop layer (CESL) 192 and an interlayer dielectric (ILD) layer 194 formed in sequence. In some examples, the CESL 192 includes a silicon nitride layer, silicon oxide layer, a silicon oxynitride layer, and/or other suitable materials having a different etch selectivity than the ILD layer 194. The CESL 192 may be formed by plasma-enhanced chemical vapor deposition (PECVD) process and/or other suitable deposition or oxidation processes. The ILD layer 194 is then deposited over the CESL 192. In some embodiments, the ILD layer 194 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 192. The ILD layer 194 may be deposited by a PECVD process or other suitable deposition technique.

After depositing the dielectric material 190, a planarization process may be performed to remove excessive materials of the dielectric material 190. For example, a planarization process includes a chemical mechanical planarization (CMP) process which removes portions of the dielectric material 190 overlying the dummy gate structures 140 and planarizes a top surface of the integrated circuit structure. In some embodiments, the CMP process also removes the hard mask layer 146 in the dummy gate structures 140 (as shown in FIG. 3) and exposes the dummy gate electrode layer 144.

Reference is made to FIGS. 5A-5C. Some dummy gate structures 140 (referring to FIG. 4) are replaced with metal gate structures 200. The metal gate replacement process may include removing a first group of the dummy gate structures 140 (referring to FIG. 4), and removing the sacrificial layers 122 (referring to FIG. 4) therebelow. The removals form gate trenches GT1 between the gate spacers 150 and openings/spaces O1 between neighboring channel layers 124. Replacement gate structures 200 are respectively formed in the gate trenches GT1 and openings/spaces O1 to surround each of the channel layers 124 suspended in the gate trenches GT1.

In the illustrated embodiments, the dummy gate structures 140 (referring to FIG. 4) are removed by using a selective etching process (e.g., selective dry etching, selective wet etching, or a combination thereof) that etches the materials in dummy gate structures 140 (referring to FIG. 4) at a faster etch rate than it etches other materials (e.g., gate spacers 150 and the dielectric material 190), thus resulting in gate trenches GT1 between corresponding gate spacers 150, with the top surface and sidewalls of the fins FS exposed in the gate trenches GT1. Subsequently, the sacrificial layers 122 in the gate trenches GT1 are etched by using another selective etching process that etches the sacrificial layers 122 at a faster etch rate than it etches the channel layers 124, thus forming openings/spaces O1 between neighboring channel layers 124. In this way, the channel layers 124 become nanosheets suspended over the substrate 110 and between the source/drain epitaxial structures 180. This step is also called a channel release process. In some embodiments, the nanosheets 124 can be interchangeably referred to as nanowires, nanoslabs and nanorings, depending on their geometry. For example, in some other embodiments, the channel layers 124 may be trimmed to have a substantial rounded shape (i.e., cylindrical) due to the selective etching process for completely removing the sacrificial layers 122. In that case, the resultant channel layers 124 can be called nanowires.

In some embodiments, the sacrificial layers 122 (referring to FIG. 4) are removed by using a selective wet etching process. In some embodiments, the sacrificial layers 122 are SiGe and the channel layers 124 are silicon allowing for the selective removal of the sacrificial layers 122. In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

The gate structures 200 may be final gates of GAA FETs. The final gate structure may be a high-k/metal gate stack, however other compositions are possible. In some embodiments, each of the gate structures 200 forms the gate associated with the multi-channels provided by the plurality of nanosheets 124. For example, high-k/metal gate structures 200 are formed within the openings O1 provided by the release of nanosheets 124. In various embodiments, the high-k/metal gate structure 200 includes a gate dielectric layer 202 around the nanosheets 124 and a gate metal layer 204 formed around the gate dielectric layer 202 and filling a remainder of gate trenches GT1. Formation of the high-k/metal gate structures 200 may include one or more deposition processes to form various gate materials, followed by a CMP processes to remove excessive gate materials. Thus, n-type devices ND1-ND3 (e.g., NMOSFET) and p-type devices PD1-PD3 (e.g., PMOSFET), shown as GAA FETs, are formed.

In some embodiments, the gate dielectric layer 202 includes an interfacial layer formed around the nanosheets 124 and a high-k gate dielectric layer formed around the interfacial layer. The interfacial layer may be silicon oxide formed on exposed surfaces of semiconductor materials in the gate trenches GT1 by using, for example, thermal oxidation, chemical oxidation, wet oxidation or the like. As a result, surface portions of the nanosheets 124 and the substrate 110 exposed in the gate trenches GT1 are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 204 includes one or more metal layers. For example, the gate metal layer 204 may include one or more work function metal layers stacked one over another and a fill metal filling up a remainder of gate trenches GT1. The one or more work function metal layers in the gate metal layer 204 provide a suitable work function for the high-k/metal gate structures 200. The work function metal layers may include TiN, TaN, TiAl, TiAlN, TaAl, TaAlN, TaAlC, TaCN, WNC, Co, Ni, Pt, W, or combination thereof. NMOSFET and PMOSFET may include the same work function material, or different work function materials. For example, n-type work function metals in the region NT for NMOSFET may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. P-type work function metal in the region PT for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 204 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. One for more lithography and patterning processes may be performed for forming the work-function metals for NMOSFET and forming the work-function metals for PMOSFET.

In some embodiments, before or after replacing the first group of the dummy gate structures 140 with the metal gate structures 200, a second group of dummy gate structures 140 is replaced with isolation features 210, which may also be referred to as dielectric gates. The dielectric gate replacement process may include removing the second group of the dummy gate structures 140 (referring to FIG. 4), and removing the sacrificial layers 122 and channel layers 124 (referring to FIG. 4) therebelow. The removals form gate trenches GT2 between the gate spacers 150 and between the inner spacers 160. The isolation features 210 are respectively formed in the gate trenches GT2. In some embodiments, the isolation features 210 includes suitable dielectric materials, such as silicon oxide (SiO₂), a silicon nitride (SiN), a silicon carbide (SiC), a silicon oxynitride (SiON), other suitable materials, and/or combinations thereof. The dielectric material may be deposited by a PECVD process or other suitable deposition technique. After depositing the dielectric material, a planarization process may be performed to remove excessive materials of the dielectric material. For example, a planarization process includes a chemical mechanical planarization (CMP) process which removes portions of the dielectric material 190 overlying gate structures 140/200 and planarizes a top surface of the integrated circuit structure.

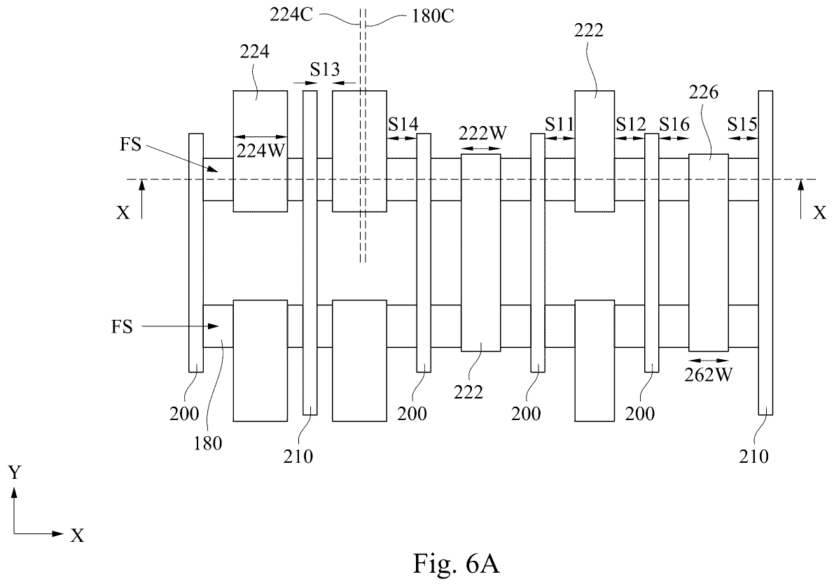

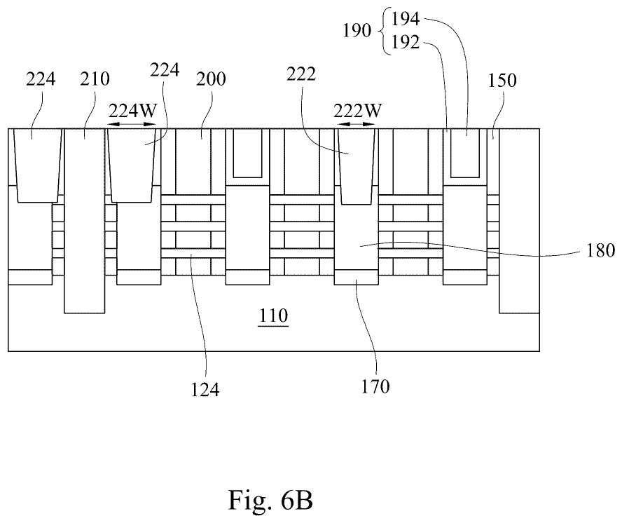

Reference is made to FIGS. 6A and 6B. Front-side source/drain contacts 222-226 are formed over the source/drain epitaxial structures 180. In some embodiments, the formation of the front-side source/drain contacts 222-226 includes etching source/drain contact openings through the dielectric material 190 to expose top surfaces of the source/drain epitaxial structures 180, and depositing one or more metal materials into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 222-226. The source/drain contacts 222-226 may include a single metal material or multiple metal material layers. The source/drain contacts 222-226 may be isolated from the gate structure 200 by the gate spacers 150.

In some embodiments, prior to depositing the metal materials, metal silicide regions may be formed on exposed top surfaces of the source/drain epitaxial structures 180 by using a silicidation process. Silicidation may be formed by blanket depositing a metal layer over the exposed source/drain epitaxial structures 180, annealing the metal layer such that the metal layer reacts with silicon (and germanium if present) in the source/drain epitaxial structures 180 to form the metal silicide regions, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions may be between the source/drain epitaxial structures 180 and the source/drain contacts 222-226.

In some embodiments, from the layout top view as shown in FIG. 6A, the front-side source/drain contacts 222-226 may be in an elongated shape extending along a same direction as the gate structures 200 extend along. For example, the front-side source/drain contacts 222-226 may be a rectangular shape or an ellipse shape. The front-side source/drain contact 222 is between and immediately adjacent to opposite two gate structures 200, while each of the front-side source/drain contact 224 and 226 are between and immediately adjacent to one of the isolation features 210 and one of the gate structures 200.

In some embodiments of the present disclosure, while the isolation features 210 are configured to cut the fins FS, the front-side source/drain contacts 224 may extend toward said one of the isolation features 210, thereby enlarging a width 224W of the front-side source/drain contacts 224. For example, the width 224W of the front-side source/drain contacts 224 is greater than a width 222W of the front-side source/drain contacts 222. With the wider contacts, a contact area between the front-side source/drain contacts 224 and the underlying source/drain epitaxial structure 180 is increased, thereby reducing a parasitic resistance therebetween. For example, a contact area between the front-side source/drain contacts 224 and the underlying source/drain epitaxial structures 180 is greater than a contact area between the front-side source/drain contacts 222 and the underlying source/drain epitaxial structure 180.

In some embodiments, for forming the wider front-side source/drain contacts 224, a wider source/drain contact opening is etched in the dielectric material 190, the gate spacers 150 adjacent to the isolation features 210, and the topmost epitaxial layer 124 adjacent to the isolation features 210. And, the formed wider front-side source/drain contacts 224 in the wider source/drain contact opening may be in contact with the gate spacers 150 and the topmost epitaxial layer 124 adjacent to the isolation features 210. In some embodiments, when the topmost epitaxial layer 124 is fully consumed, the formed wider front-side source/drain contacts 224 may be in contact with the inner spacers 160.

In the top view, the front-side source/drain contacts 222 may be spaced apart from opposite gate structures 200 by spaces S11 and S12, and the front-side source/drain contacts 224 may be spaced apart from one adjacent isolation structure 210 and one adjacent gate structure 200 respectively by spaces S13 and S14. Any one of the spaces S11, S12, and S14 is greater than the space S13. For example, a difference between the space S13 and one of the spaces S11, S12, and S14 is greater than a threshold ratio of said one of the spaces S11, S12, and S14. The spaces S11, S12, and S14 may be substantially equal to each other. For example, a difference between any two of the spaces S11, S12, and S14 is less than a threshold ratio of one of the spaces S11, S12, and S14. Through the configuration, centers of the front-side source/drain contacts 224 are offset from a center line between adjacent gate structure 200 and the isolation structure 210 in the top view. For example, a center line 224C of the backside source/drain contacts 224 extending along the direction Y is misaligned with a center line 180C of the underlying source/drain epitaxial structure 180 extending along the direction Y in FIG. 6A. In the context, the threshold ratio of the spaces may be in a range from about 1% to about 20%, such as about 5% or about 10%.

In some embodiments, front-side source/drain contacts 226 adjacent to the isolation features 210 may have the configuration the same as that of the front-side source/drain contacts 222. For example, the width 226W of the front-side source/drain contacts 226 may be similar to a width 222W of the front-side source/drain contacts 222. The width 224W of the front-side source/drain contacts 224 may be greater than a width 226W of the front-side source/drain contacts 226. The front-side source/drain contacts 226 may be spaced apart from one adjacent isolation structure 210 and one adjacent gate structure 200 respectively by spaces S15 and S16. The spaces S11, S12, and S14-S16 may be substantially equal to each other. For example, a difference between any two of the spaces S11, S12, and S14-S16 is less than a threshold ratio of one of the spaces S11, S12, and S14-S16.

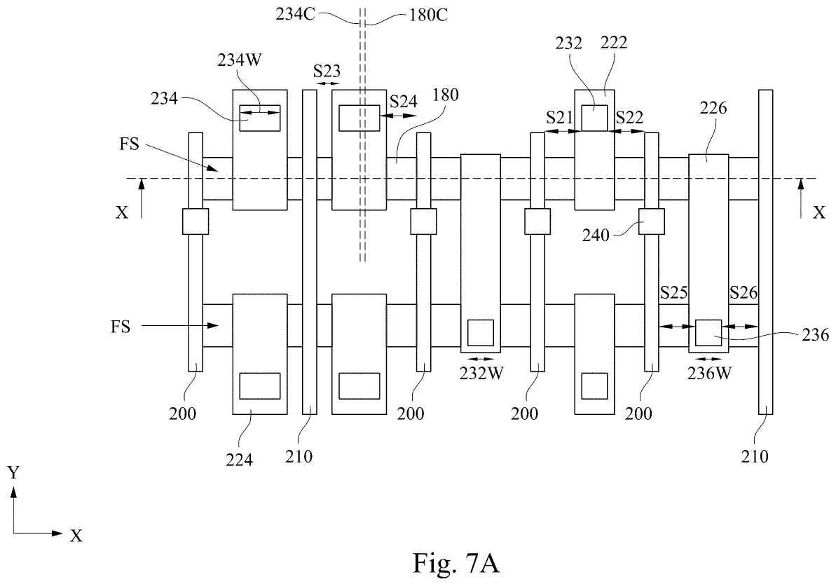

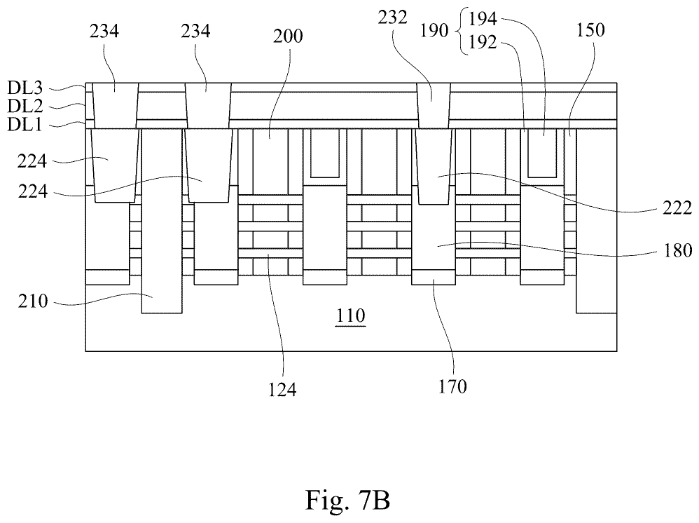

Reference is made to FIGS. 7A and 7B. One or more dielectric layers DL1-DL3 are deposited over the structure of FIGS. 6A and 6B, front-side conductive vias 232-236 may be formed in the dielectric layers DL1-DL3 over the source/drain contacts 222-226, and gate vias 240 may be formed in the dielectric layers DL1-DL3 over the gate structures 200. In some embodiments, the dielectric layers DL1-DL3 may include the same or different materials. For example, the dielectric layers DL1-DL3 may be an etch stop layer (ESL), an ILD layer, and an ESL deposited in a sequence. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some examples, the ESLs includes a silicon nitride layer, silicon oxide layer, a silicon oxynitride layer, and/or other suitable materials having a different etch selectivity than the ILD layer. Formation of the conductive vias 232-236 may include etching openings through the dielectric layers DL1-DL3 to expose top surfaces of the source/drain contacts 222-226, and depositing one or more metal materials into the openings. The metal materials may include W, Ru, Co, Cu, Ti, TiN, Ta, TaN, Mo, Ni, Pt, Ir, Rh, the like or combinations thereof. The metal materials are deposited to fill the openings by using suitable deposition techniques (e.g., CVD, PVD, ALD, the like or combinations thereof). Subsequently, a CMP process can be performed to remove excess metal materials outside the openings, while leaving metal materials in the openings to serve as the conductive vias 232-236. The conductive vias 232-236 may include a single metal material or multiple metal material layers.

The conductive vias 234 adjacent to one of the isolation features 210 may extend toward said one of the isolation features 210, thereby enlarging a width 234W of the conductive vias 234. For example, the width 234W of the conductive vias 234 is greater than a width 232W of the conductive vias 232. With the wider vias, a parasitic resistance is reduced.

In the top view, the conductive vias 232 may be spaced apart from opposite gate structures 200 by spaces S21 and S22, the conductive vias 234 may be spaced apart from one adjacent isolation structure 210 by a space S23 and one adjacent gate structure 200 by a space S24. The space S21, S22, and S24 may be substantially equal to each other and greater than the second space S23. Through the configuration, centers of the conductive vias 234 are offset from the center line between adjacent gate structure 200 and the isolation structure 210 in the top view. For example, a center line 234C of the conductive vias 234 extending along the direction Y is misaligned with a center line 180C of the underlying source/drain epitaxial structure 180 extending along the direction Y in FIG. 7A.

Some other conductive vias 236 adjacent to the isolation features 210 may have the configuration the same as that of the conductive vias 232. For example, the width 236W of the conductive vias 236 may be similar to a width 232W of the conductive vias 236. The width 234W of the conductive vias 234 may be greater than the width 236W of the conductive vias 236. The conductive vias 236 may be spaced apart from one adjacent gate structure 200 and one adjacent isolation structure 210 respectively by substantially equal spaces S25 and S26. The spaces S21-S23, S25, and S26 may be substantially equal to each other. For example, a difference between any two of the spaces S21-S23, S25, and S26 is less than a threshold ratio of one of the spaces S21-S23, S25, and S26.

Formation of the gate vias 240 may include etching openings through the dielectric layers DL1-DL3 to expose top surfaces of the gate structures 200, and depositing one or more metal materials into the openings. The metal materials may include W, Ru, Co, Cu, Ti, TiN, Ta, TaN, Mo, Ni, Pt, Ir, Rh, the like or combinations thereof. The metal materials are deposited to fill the openings by using suitable deposition techniques (e.g., CVD, PVD, ALD, the like or combinations thereof). Subsequently, a CMP process can be performed to remove excess metal materials outside the openings, while leaving metal materials in the openings to serve as the gate vias 240. The gate vias 240 may include a single metal material or multiple metal material layers.

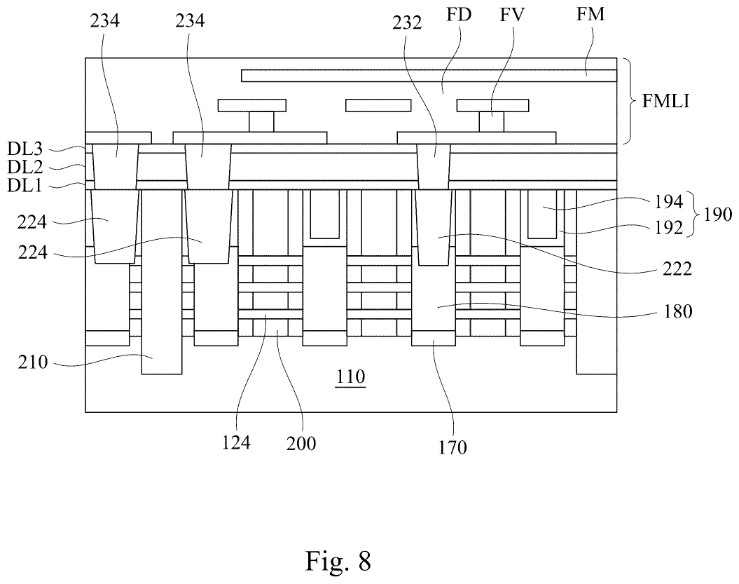

FIG. 8 illustrates formation of a front-side multilayer interconnection (MLI) structure FMLI over the dielectric layers DL1-DL3 and the conductive vias 232-236. The front-side MLI structure FMLI may include one or more front-side metallization layers. The number of front-side metallization layers may vary according to design specifications of the integrated circuit structure. The front-side metallization layers each comprise one or more front-side inter-metal dielectric (IMD) layers (e.g., dielectric layers FD), one or more horizontal interconnects (e.g., metal lines FM) respectively extending horizontally in the IMD layers, and one or more vertical interconnects (e.g., metal via FV) respectively extending vertically in the IMD layers. The metal via FV may connect one of the metal lines FM to another one of the metal lines FM. The metal lines FM of the metallization layers of the front-side MLI structure FMLI may include signal conductors in contact with the conductive vias 232-236 to make signal electrical connection to the front-side source/drain contacts 222-226. The metal lines FM of the metallization layers of the front-side MLI structure FMLI may also include power conductors serving a power rails (e.g., the high power rail and/or the lower power rail) in the device.

The front-side metallization layers can be formed using, for example, a single damascene process, a dual damascene process, the like, or combinations thereof. In some embodiments, the dielectric layers FD may include low-k dielectric materials having k values, for example, lower than about 4.0 or even 2.0 disposed between such conductive features. In some embodiments, the dielectric layers FD may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The metal lines and vias FM and FV may comprise metal materials such as W, Ru, Co, Cu, Ti, TiN, Ta, TaN, Mo, Ni, combinations thereof, or the like. In some embodiments, the metal lines and vias FM and FV may further comprise one or more barrier/adhesion layers (not shown) to protect the respective IMD layers FD from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

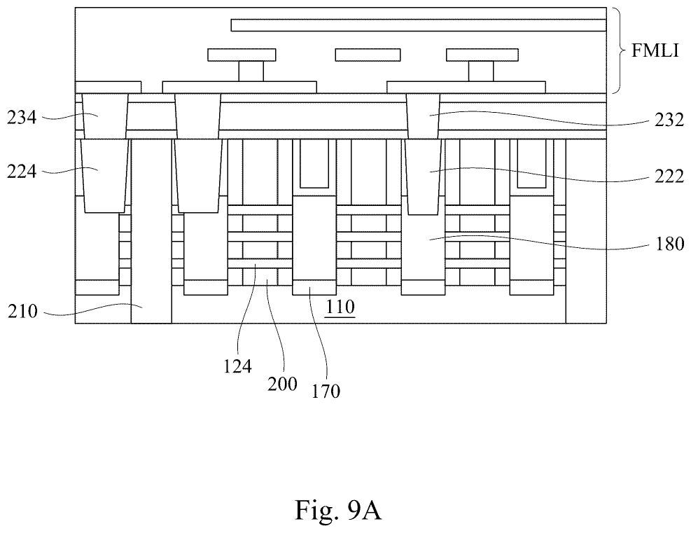

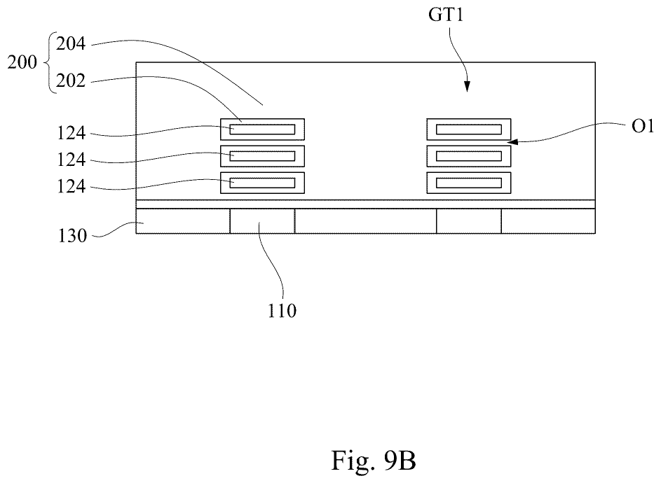

Reference is made to FIGS. 9A and 9B. After the formation of the front-side MLI structure FMLI, a planarization process (e.g., a CMP process, or a grinding process) is performed to thinning down the substrate 110. Bottom surfaces of the isolation structures 130 and 210 may be exposed after the planarization process.

FIGS. 10A and 10B illustrate formation of back-side source/drain contacts 262 and 264 over backsides of the source/drain epitaxial structures 180. In some embodiments, the formation of the back-side source/drain contacts 262 and 264 includes etching openings through the substrate 110 to expose the backsides of the source/drain epitaxial structures 180, and depositing one or more metal materials into the openings. The metal materials may include W, Ru, Co, Cu, Ti, TiN, Ta, TaN, Mo, Ni, the like or combinations thereof. The metal materials are deposited to fill the openings by using suitable deposition techniques (e.g., CVD, PVD, ALD, the like or combinations thereof). Subsequently, a CMP process can be performed to remove excess metal materials outside the openings, while leaving metal materials in the openings to serve as the back-side source/drain contacts 262 and 264.

In some embodiments, prior to depositing the metal materials, forming dielectric liners SR on sidewalls of the openings. Formation of the dielectric liners SR may include depositing a conformal dielectric layer over the backside of the substrate 110, into the openings, and over the exposed backsides of the source/drain epitaxial structures 180, and performing an anisotropic etching process to remove horizontal portions of the conformal dielectric layer, thereby exposing the backsides of the source/drain epitaxial structures 180. The conformal dielectric layer may include suitable dielectric materials, such as silicon nitride, silicon oxynitride, the like, or the combination thereof. Remaining vertical portions of the conformal dielectric layer may form the dielectric liners SR. The dielectric liners SR surrounds the back-side source/drain contacts 262 and 264, and allows the connection between the back-side source/drain contacts 262 and 264. Also, the dielectric liners SR spaces the back-side source/drain contacts 262 and 264 from the substrate 110.

In some embodiments, prior to depositing the metal materials, metal silicide regions may be formed on exposed backsides of the source/drain epitaxial structures 180 by using a silicidation process. Silicidation may be formed by blanket depositing a metal layer over the exposed backsides of the source/drain epitaxial structures 180, annealing the metal layer such that the metal layer reacts with silicon (and germanium if present) in the source/drain epitaxial structures 180 to form the metal silicide regions, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions may be between the back-side source/drain contacts 262 and 264 and the source/drain epitaxial structures 180.

In some embodiments, a lower portion of the source/drain epitaxial structures 180 (near the frontside) has a lower dopant concentration than a dopant concentration of a higher portion of the source/drain epitaxial structures 180 (near the backside). Thus, the back-side source/drain contacts may suffer higher parasitic resistance (Rp) due to the lower dopant concentration at the backside of the source/drain epitaxial structures 180.

In some embodiments of the present embodiments, by enlarging the back-side source/drain contacts 264, a landing area of the back-side source/drain contacts 264 can be enlarged, thereby reducing parasitic resistance. In some embodiments of the present disclosure, while the isolation features 210 are configured to cut the fins FS, the back-side source/drain contacts 264 adjacent to one of the isolation features 210 may extend toward said one of the isolation features 210, thereby enlarging a width 264W of the back-side source/drain contacts 262. As shown in FIG. 10A, the width 264W of the back-side source/drain contacts 264 is greater than a width 262W of the back-side source/drain contacts 262. With the wider contacts, a contact area between the back-side source/drain contacts 264 and the corresponding source/drain epitaxial structure 180 is increased, thereby reducing a parasitic resistance therebetween. For example, a contact area between the back-side source/drain contacts 264 and the source/drain epitaxial structures 180 is greater than a contact area between the back-side source/drain contacts 262 and the source/drain epitaxial structure 180. Furthermore, since the back-side source/drain contacts 264 is enlarged by extending it toward an isolation structure 210, a short between the source/drain contacts 264 and a gate structure 200 can be avoided.

In the present embodiments, a ratio of the width 264W and the width 262W may be in a range from about 1.05 to about 3. If the ratio of the width 264W and the width 262W is less than about 1.05, the parasitic resistance may not be effectively reduced. If the ratio of the width 264W and the width 262W is greater than about 3, the source/drain contact 264 may merge with another source/drain contact 264 of the same or another transistor or short with the gate structure 200.

In the present embodiments, a size of the back-side source/drain contacts 264 may be greater than a size of the front-side source/drain contacts 224. For example, a ratio of the width 264W of the back-side source/drain contacts 264 and the width 224W of the front-side source/drain contacts 224 may be in a range from about 1.2 to about 5. If the ratio of the width 264W and the width 224W is less than about 1.2, the parasitic resistance may not be effectively reduced. If the ratio of the width 264W and the width 224W is greater than about 5, the source/drain contact 264 may merge with another source/drain contact 264 of the same or another transistor or short with the gate structure 200.

In some embodiments, for forming the wider back-side source/drain contacts 264, a wider source/drain contact opening is etched in the substrate 110, the dielectric isolation layer 170, and the inner spacers 160 adjacent to the isolation features 210. And, the formed wider back-side source/drain contacts 264 in the wider source/drain contact opening may be in contact with the inner spacers 160.

In the top view, the back-side source/drain contacts 262 may be spaced apart from opposite gate structures 200 by spaces S31 and S32, and the back-side source/drain contacts 264 may be spaced apart from one adjacent isolation structure 210 and one adjacent gate structure 200 respectively by spaces S33 and S34. Any one of the spaces S31, S32, S34 may be greater than the space S33. For example, a difference between the space S33 and one of the spaces S31, S32, S34 is greater than a threshold ratio of said one of the spaces S31, S32, S34. For example, a ratio between the space S33 and the space S34 is in a range from about 0.1 to about 0.8. The spaces S31, S32, S34 may be substantially equal to each other. For example, a difference between any two of the spaces S31, S32, S34 is less than a threshold ratio of one of the spaces S31, S32, S34. Through the configuration, centers of the back-side source/drain contacts 264 are offset from a center line between adjacent gate structure 200 and the isolation structure 210 in the top view. For example, a center line 264C of the back-side source/drain contacts 264 extending along the direction Y is misaligned with a center line 180C of the underlying source/drain epitaxial structure 180 extending along the direction Y in FIG. 10A.

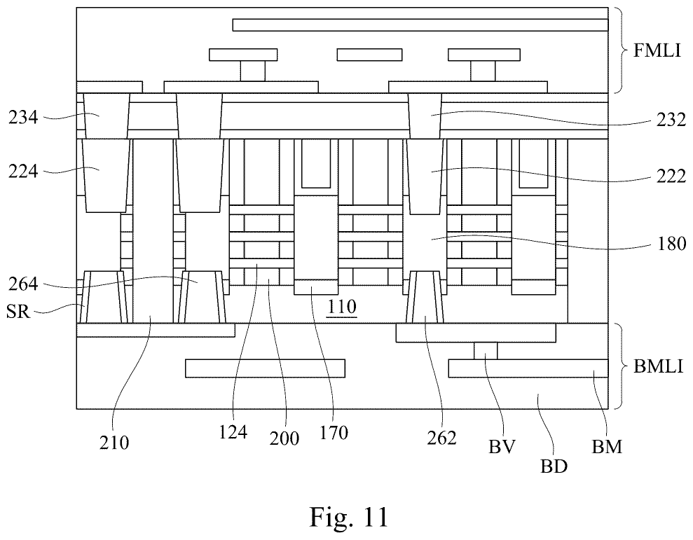

FIG. 11 illustrates formation of a back-side multilayer interconnection (MLI) structure BMLI over the substrate 110. The back-side MLI structure BMLI may include at least three back-side metallization layers. The number of back-side metallization layers may vary according to design specifications of the integrated circuit structure. The back-side metallization layers each comprise one or more back-side inter-metal dielectric (IMD) layers, one or more horizontal interconnects respectively extending horizontally in the IMD layers, and one or more vertical interconnects respectively extending vertically in the IMD layers. For example, the back-side metallization layer comprises IMD layers BD, horizontal interconnects (e.g., metal lines BM) and vertical interconnects (e.g., metal via BV). The metal via BV may connect one of the metal lines BM to another one of the metal lines BM. The metal lines BM may include power rails. The metal lines BM are in contact with the back-side source/drain contacts 262 and 264 to make power electrical connection from the power rails (e.g., the high power rail and/or the lower power rail) to the source/drain epitaxial structure 180. In some embodiments, a width and/or a height of the back-side metal lines BM is greater than a width and/or a height of the front-side metal lines FM, and a number of the back-side metal lines BM is less than a number of the front-side metal lines FM.

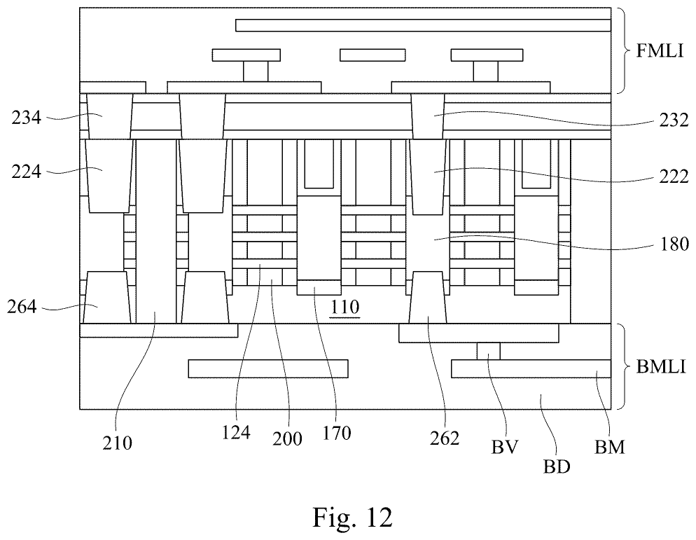

FIG. 12 is a cross-sectional view of an integrated circuit structure according to some embodiments of the present disclosure. Details of the present embodiments are similar to that of the embodiments of FIGS. 1-11, except that the dielectric liners SR (referring to FIG. 11) may be omitted. In the present embodiments, the isolation structure 130 can electrically isolate one fin from another, and as the back-side source/drain contacts 262 and 264 on the same fin can be connected to the same power rails. Other details of the present embodiments are similar to those illustrated in the embodiments of FIGS. 1-11, and therefore not repeated herein.

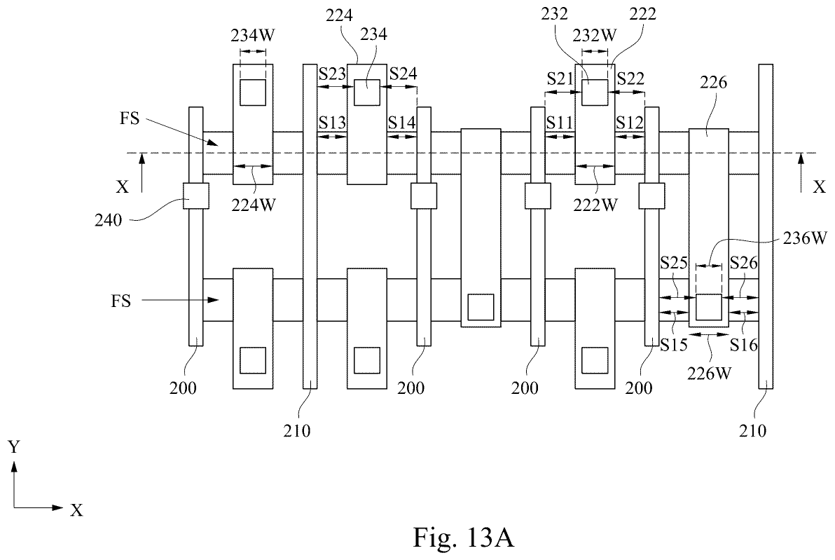

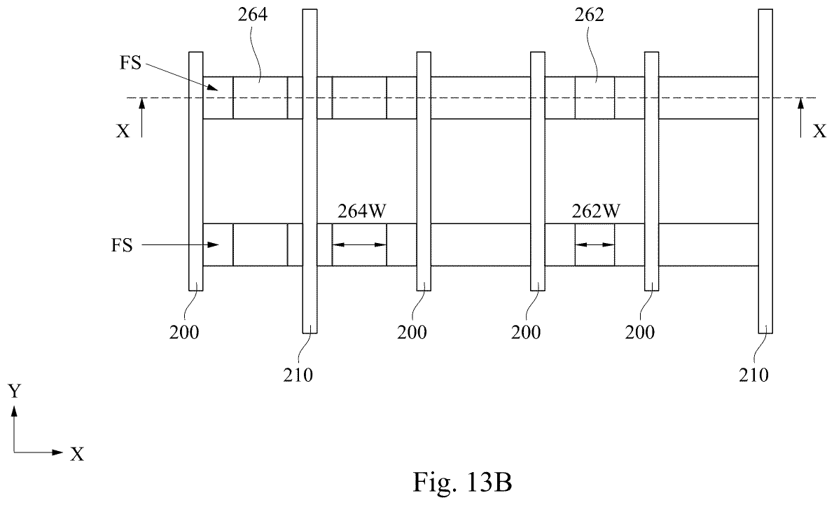

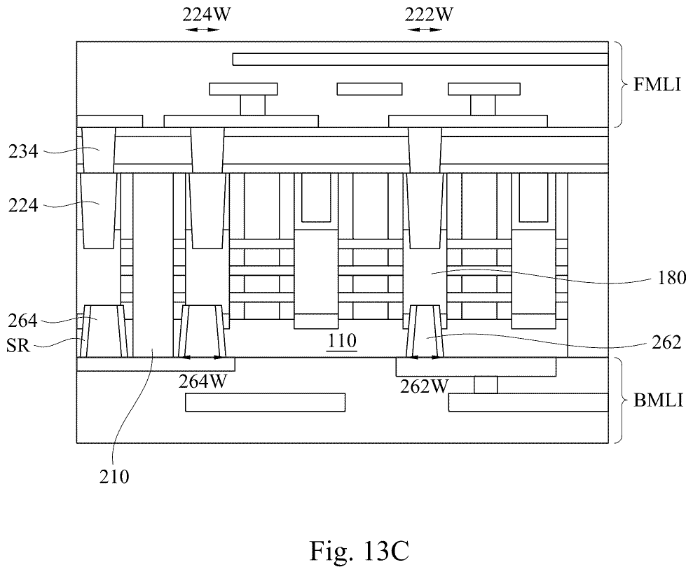

FIGS. 13A and 13B illustrate layouts of an integrated circuit structure according to some embodiments of the present disclosure. FIG. 13C illustrates a cross-sectional view taken along line X-X in FIGS. 13A and 13B. Details of the present embodiments are similar to that of the embodiments of FIGS. 1-11, except that centers of the front-side source/drain contacts 224 and the front-side conductive vias 234 are aligned with a center line between adjacent gate structure 200 and the isolation structure 210 in the top view, not offset from the center line between adjacent gate structure 200 and the isolation structure 210. Stated differently, the front-side source/drain contacts 224 and the front-side conductive vias 234 may not extend toward the adjacent isolation features 210.

For example, the width 224W of the source/drain contacts 224 may be substantially equal to the width 222W of the front-side source/drain contacts 222 and the width 226W of the front-side source/drain contacts 226. And, the spaces S11, S12, S13, S14, S15, and S16 may be substantially equal to each other. For example, a difference between any two of the spaces S11-S16 is less than a threshold ratio of one of the spaces S11-S16. Similarly, the width 234W of the conductive vias 234 may be substantially equal to the width 232W of the conductive vias 232 and the width 236W of the conductive vias 236. And, the spaces S21, S22, S23, S24, S25, and S26 may be substantially equal to each other. For example, a difference between any two of the spaces S21-S26 is less than a threshold ratio of one of the spaces S21-S26.

In the present embodiments, as the configuration of the embodiments of FIGS. 1-11, a center of the back-side source/drain contacts 264 remain offset from the center line between adjacent gate structure 200 and the isolation structure 210 in the top view in the top view. Other details of the present embodiments are similar to those illustrated in the embodiments of FIGS. 1-11, and therefore not repeated herein.

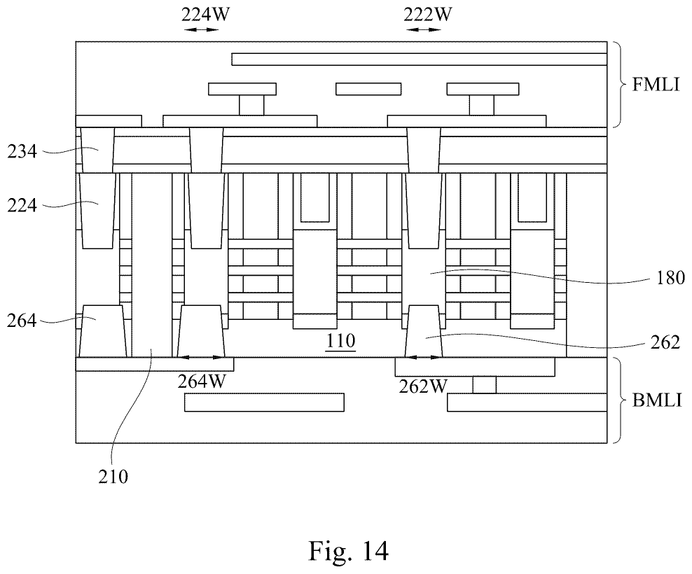

FIG. 14 is a cross-sectional view of an integrated circuit structure according to some embodiments of the present disclosure. Details of the present embodiments are similar to that of the embodiments of FIGS. 13A-13C, except that the dielectric liners SR (referring to FIG. 13C) may be omitted. In the present embodiments, the isolation structure 130 can electrically isolate one fin from another, and as the back-side source/drain contacts 262 and 264 on the same fin can be connected to the same power rails. Other details of the present embodiments are similar to those illustrated in the embodiments of FIGS. 13A-13C, and therefore not repeated herein.

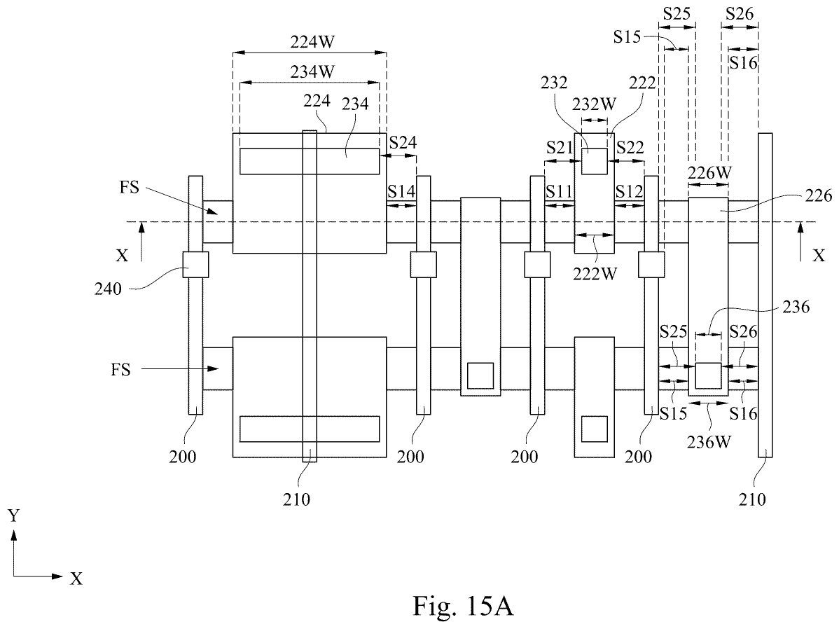

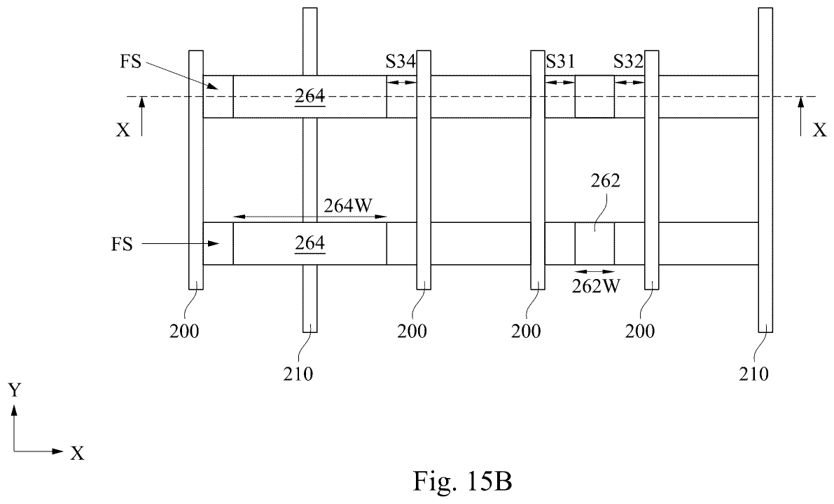

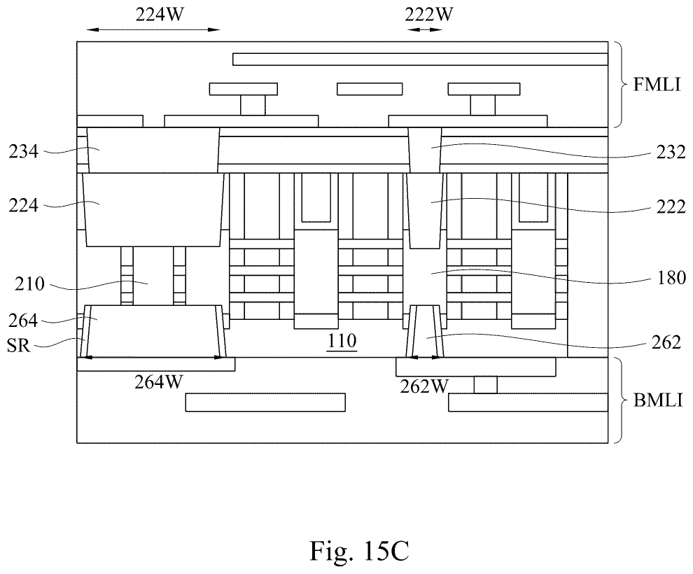

FIGS. 15A and 15B illustrate layouts of an integrated circuit structure according to some embodiments of the present disclosure. FIG. 15C illustrates a cross-sectional view taken along line X-X in FIGS. 15A and 15B. Details of the present embodiments are similar to that of the embodiments of FIGS. 1-11, except that the front-side source/drain contacts 224, the front-side conductive vias 234, and the back-side source/drain contacts 264 extend across an adjacent one isolation structure 210. Stated differently, the source/drain contacts 224 on opposite sides of the isolation structure 210 re merged, the front-side conductive vias 234 on opposite sides of the isolation structure 210 are merged, and the source/drain contacts 264 on opposite sides of the isolation structure 210 are merged. For example, the width 224W of the front-side source/drain contacts 224 is greater than twice the sum of the width 222W of the front-side source/drain contacts 222 and one of the spaces S11, S12, S14-S16. For example, the width 234W of the front-side conductive vias 234 is greater than twice the sum of the width 232W of the front-side conductive vias 232 and one of the spaces S21, S22, S24-S26. For example, the width 264W of the back-side source/drain contacts 264 is greater than twice the sum of the width 262W of the back-side source/drain contacts 262 and one of the spaces S31, S32, S34.

In some embodiments, for forming the wider front-side contacts 224, a wider source/drain contact opening is etched in the dielectric material 190, the gate spacers 150 adjacent to the isolation features 210, and the topmost epitaxial layer 124 adjacent to the isolation features 210, and the isolation features 210. And, the formed wider front-side source/drain contacts 224 in the wider source/drain contact opening may be in contact with two source/drain epitaxial structures 180, the gate spacers 150, and the isolation features 210. In some embodiments, when the topmost epitaxial layer 124 is fully consumed, the formed wider front-side source/drain contacts 224 may be in contact with the inner spacers 160.

In some embodiments, for forming the wider back-side source/drain contacts 264, a wider source/drain contact opening is etched in the substrate 110, the dielectric isolation layer 170, and the inner spacers 160 adjacent to the isolation features 210, and the isolation features 210. And, the formed wider back-side source/drain contacts 264 in the wider source/drain contact opening may be in contact with the two source/drain epitaxial structures 180, the inner spacers 160, and the isolation features 210. Other details of the present embodiments are similar to those illustrated in the embodiments of FIGS. 1-11, and therefore not repeated herein.

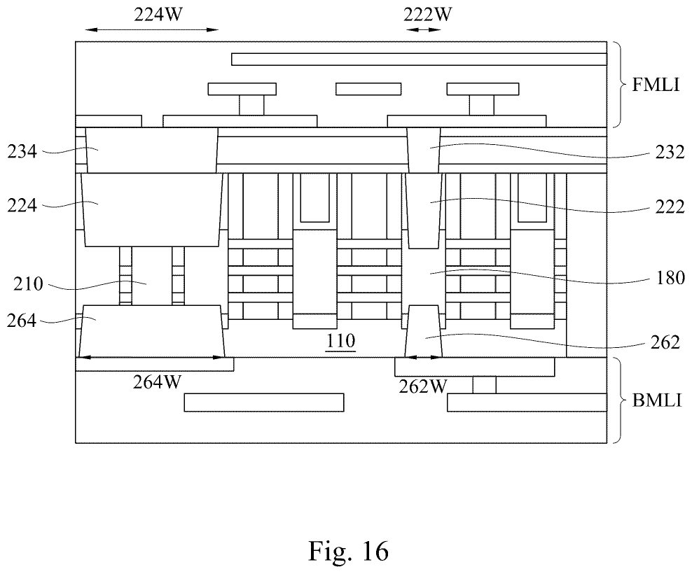

FIG. 16 is a cross-sectional view of an integrated circuit structure according to some embodiments of the present disclosure. Details of the present embodiments are similar to that of the embodiments of FIGS. 15A-15C, except that the dielectric liners SR (referring to FIG. 15C) may be omitted. In the present embodiments, the isolation structure 130 can electrically isolate one fin from another, and as the back-side source/drain contacts 262 and 264 on the same fin can be connected to the same power rails. Other details of the present embodiments are similar to those illustrated in the embodiments of FIGS. 15A-15C, and therefore not repeated herein.

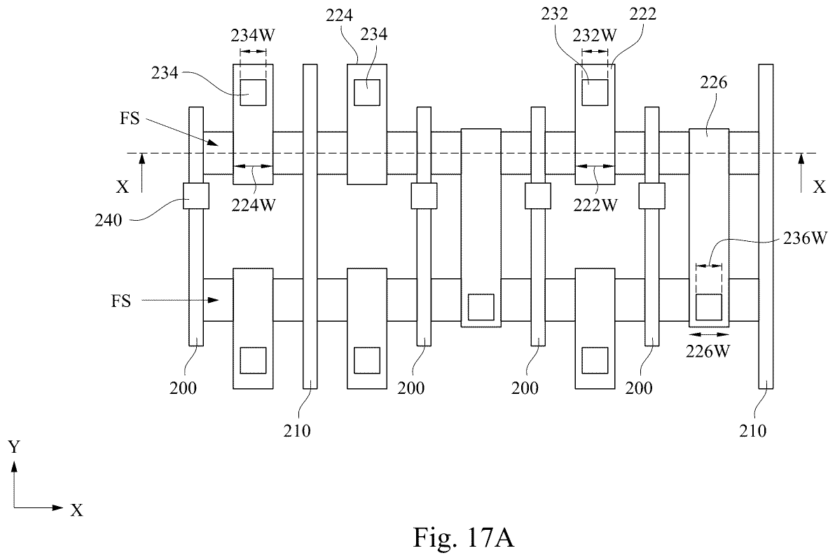

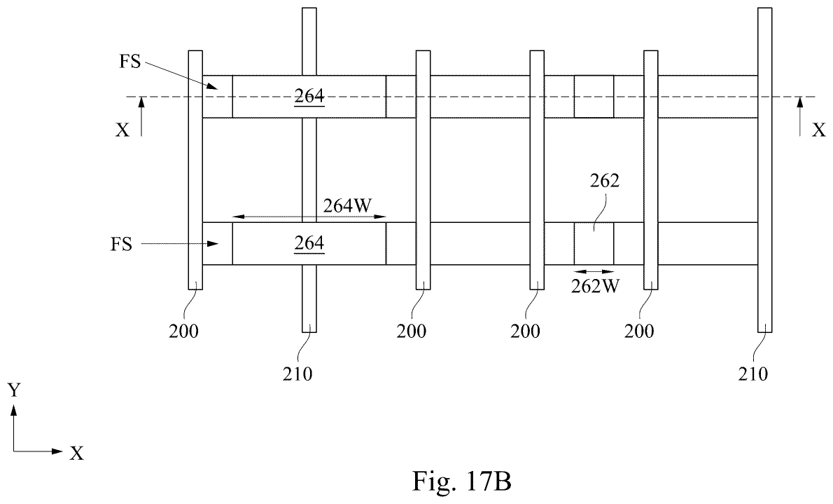

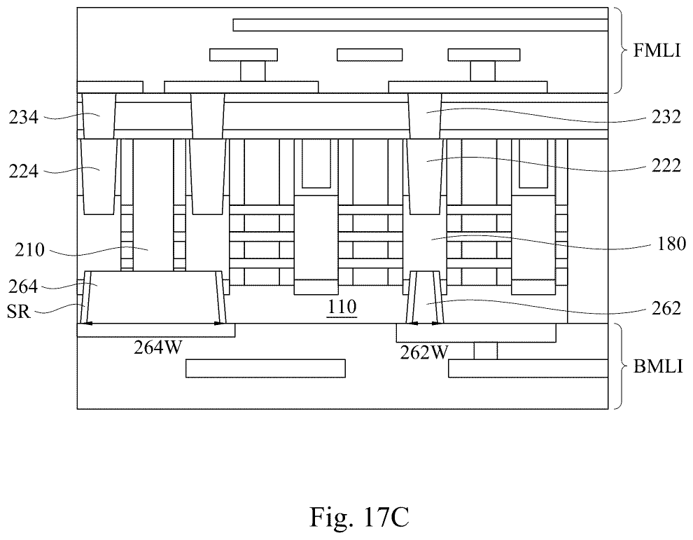

FIGS. 17A and 17B illustrate layouts of an integrated circuit structure according to some embodiments of the present disclosure. FIG. 17C illustrates a cross-sectional view taken along line X-X in FIGS. 17A and 17B. Details of the present embodiments are similar to that of the embodiments of FIGS. 15A-15C, except that centers of the front-side source/drain contacts 224 and the front-side conductive vias 234 are aligned with a center line between adjacent gate structure 200 and the isolation structure 210 in the top view. Stated differently, the front-side source/drain contacts 224 and the front-side conductive vias 234 may not extend across the isolation features 210. Other details of the present embodiments are similar to those illustrated in the embodiments of FIGS. 15A-15C, and therefore not repeated herein.

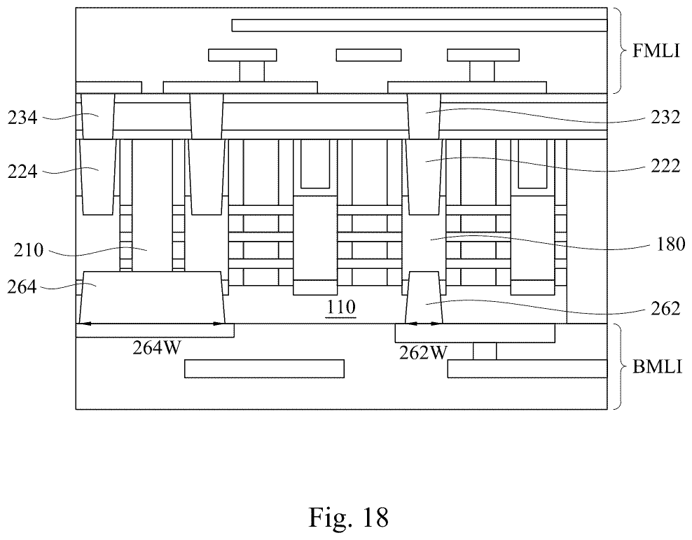

FIG. 18 is a cross-sectional view of an integrated circuit structure according to some embodiments of the present disclosure. Details of the present embodiments are similar to that of the embodiments of FIGS. 17A-17C, except that the dielectric liners SR (referring to FIG. 17C) may be omitted. In the present embodiments, the isolation structure 130 can electrically isolate one fin from another, and as the back-side source/drain contacts 262 and 264 on the same fin can be connected to the same power rails. Other details of the present embodiments are similar to those illustrated in the embodiments of FIGS. 17A-17C, and therefore not repeated herein.

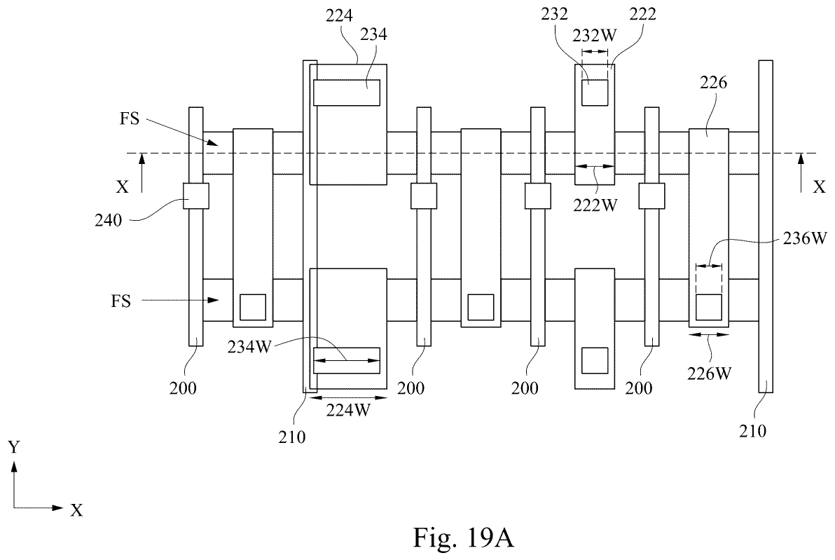

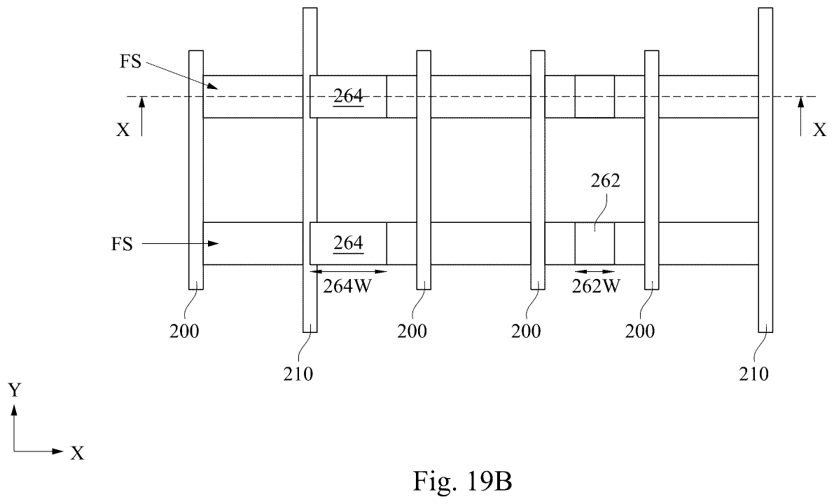

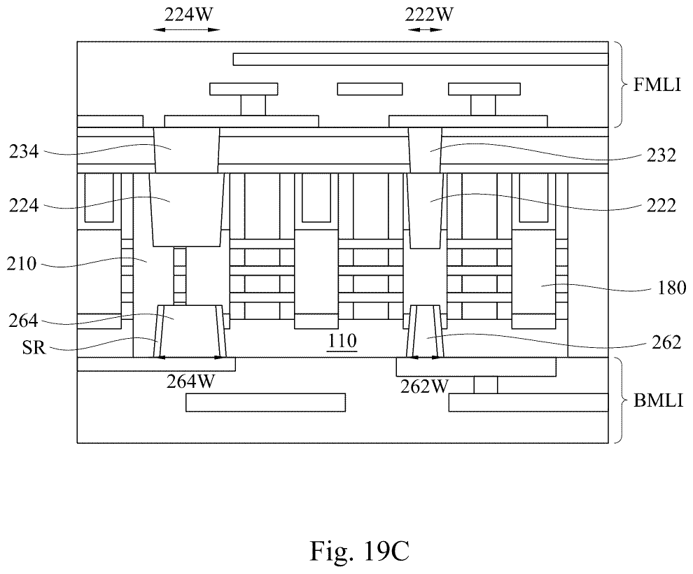

FIGS. 19A and 19B illustrate layouts of an integrated circuit structure according to some embodiments of the present disclosure. FIG. 19C illustrates a cross-sectional view taken along line X-X in FIGS. 19A and 19B. Details of the present embodiments are similar to that of the embodiments of FIGS. 1-11, except that the front-side source/drain contacts 224, the front-side conductive vias 234, and the back-side source/drain contacts 264 extend into an adjacent one isolation structure 210. For example, the width 224W of the front-side source/drain contacts 224 is greater than the sum of the width 222W of the front-side source/drain contacts 222 and one of the spaces S11, S12, S14-S16. For example, the width 234W of the front-side conductive vias 234 is greater than the sum of the width 232W of the front-side conductive vias 232 and one of the spaces S21, S22, S24-S26. For example, the width 264W of the back-side source/drain contacts 264 is greater than the sum of the width 262W of the back-side source/drain contacts 262 and one of the spaces S31, S32, S34.

In some embodiments, for forming the wider front-side contacts 224, a wider source/drain contact opening is etched in the dielectric material 190, the gate spacers 150 adjacent to the isolation features 210, and the topmost epitaxial layer 124 adjacent to the isolation features 210, and the isolation features 210. And, the formed wider front-side source/drain contacts 224 in the wider source/drain contact opening may be in contact with one source/drain epitaxial structure 180, the gate spacers 150, and the isolation features 210. In some embodiments, when the topmost epitaxial layer 124 is fully consumed, the formed wider front-side source/drain contacts 224 may be in contact with the inner spacers 160.

In some embodiments, for forming the wider back-side source/drain contacts 264, a wider source/drain contact opening is etched in the substrate 110, the dielectric isolation layer 170, and the inner spacers 160 adjacent to the isolation features 210, and the isolation features 210. And, the formed wider back-side source/drain contacts 264 in the wider source/drain contact opening may be in contact with the source/drain epitaxial structure 180, the inner spacers 160, and the isolation features 210. Other details of the present embodiments are similar to those illustrated in the embodiments of FIGS. 1-11, and therefore not repeated herein.

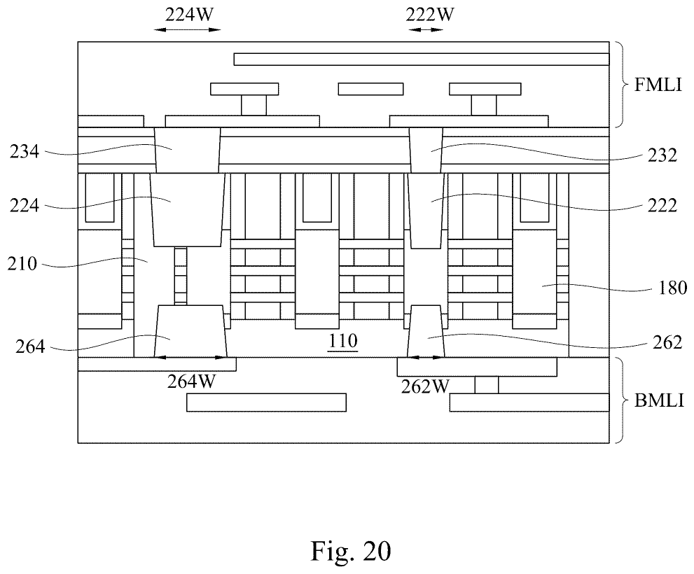

FIG. 20 is a cross-sectional view of an integrated circuit structure according to some embodiments of the present disclosure. Details of the present embodiments are similar to that of the embodiments of FIGS. 19A-19C, except that the dielectric liners SR (referring to FIG. 19C) may be omitted. In the present embodiments, the isolation structure 130 can electrically isolate one fin from another, and as the back-side source/drain contacts 262 and 264 on the same fin can be connected to the same power rails. Other details of the present embodiments are similar to those illustrated in the embodiments of FIGS. 19A-19C, and therefore not repeated herein.

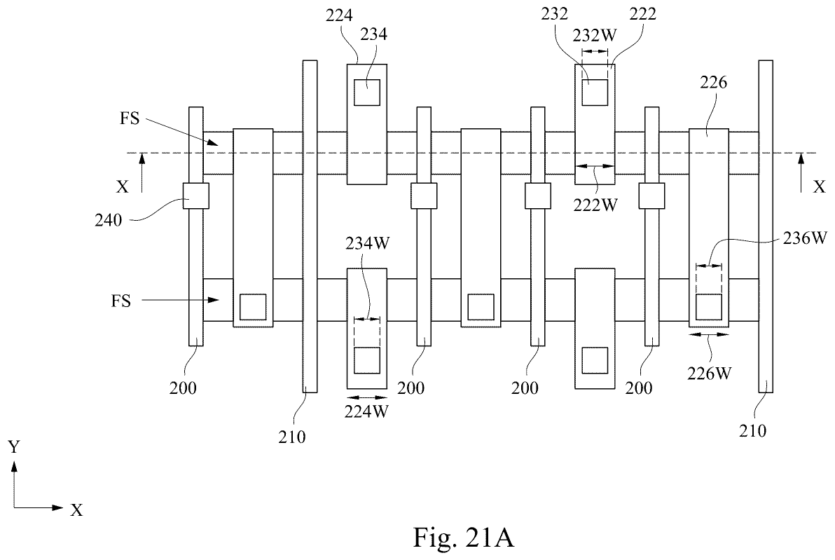

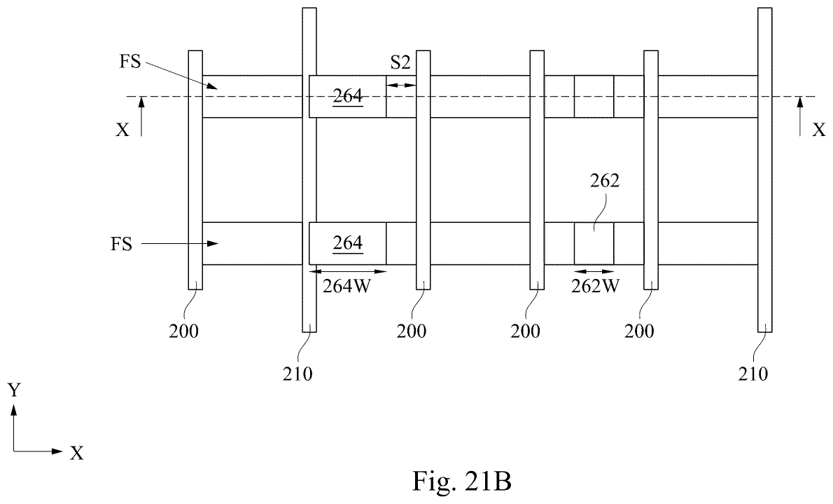

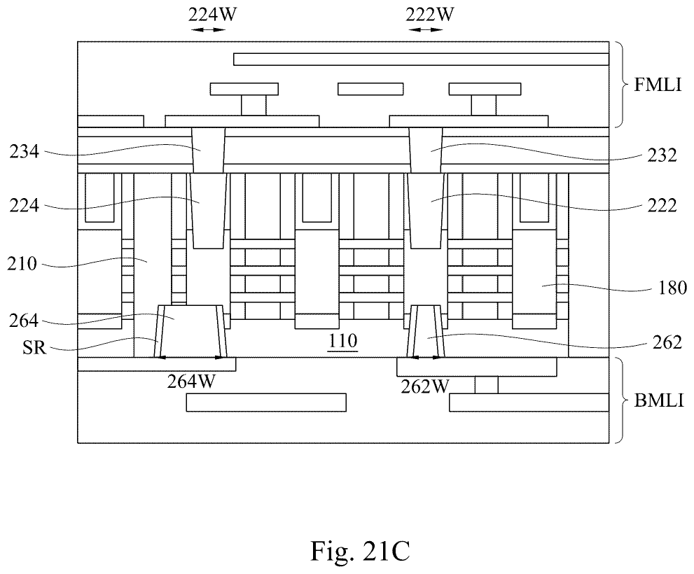

FIGS. 21A and 21B illustrate layouts of an integrated circuit structure according to some embodiments of the present disclosure. FIG. 21C illustrates a cross-sectional view taken along line X-X in FIGS. 21A and 21B. Details of the present embodiments are similar to that of the embodiments of FIGS. 19A-19C, except that centers of the front-side source/drain contacts 224 and the front-side conductive vias 234 are aligned with a center line between adjacent gate structure 200 and the isolation structure 210 in the top view. Stated differently, the front-side source/drain contacts 224 and the front-side conductive vias 234 may not extend into the isolation features 210. Other details of the present embodiments are similar to those illustrated in the embodiments of FIGS. 19A-19C, and therefore not repeated herein.

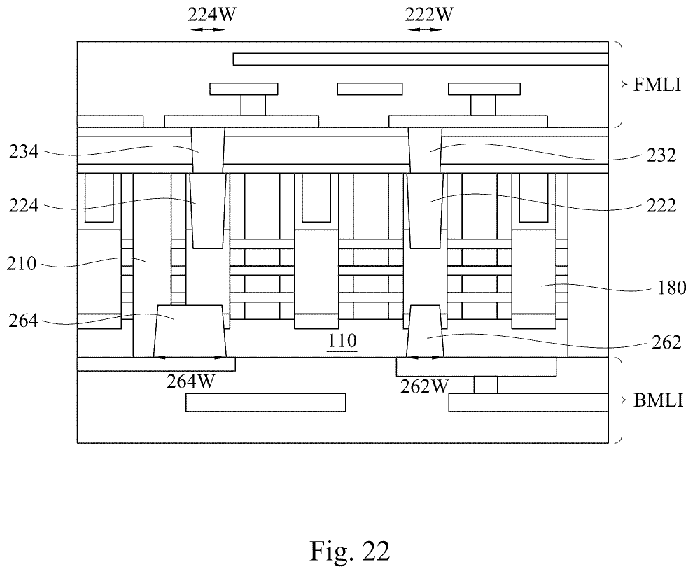

FIG. 22 is a cross-sectional view of an integrated circuit structure according to some embodiments of the present disclosure. Details of the present embodiments are similar to that of the embodiments of FIGS. 21A-21C, except that the dielectric liners SR (referring to FIG. 21C) may be omitted. In the present embodiments, the isolation structure 130 can electrically isolate one fin from another, and as the back-side source/drain contacts 262 and 264 on the same fin can be connected to the same power rails. Other details of the present embodiments are similar to those illustrated in the embodiments of FIGS. 21A-21C, and therefore not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a backside source/drain contact is extended, thereby enlarging a landing area to reduce a parasitic resistance due to low dopant concentration at the backside of the source/drain epitaxial structures. Another advantage is that since the back-side source/drain contacts 264 is extended toward/into/across an isolation structure disposed at a fin end, a short between the source/drain contact and a gate structure can be avoided.

In some embodiments of the present disclosure, an integrated circuit (IC) structure includes a channel region, a gate structure, an isolation structure, a source/drain epitaxial structure, and a backside source/drain contact. The channel region extends along a first direction. The gate structure is over the channel region. The gate structure and the isolation structure extend along a second direction different from the first direction and spaced apart from each other. The source/drain epitaxial structure is between the gate structure and the isolation structure. The backside source/drain contact is on a backside of the source/drain epitaxial structure. A space between the backside source/drain contact and the isolation structure is less than a space between the backside source/drain contact and the gate structure in a first top view.

In some embodiments of the present disclosure, an IC structure includes a first channel region, a second channel region, a third channel region, a first gate structure, a second gate structure, a third gate structure, an isolation structure, a first source/drain epitaxial structure, a second source/drain epitaxial structure, a first backside source/drain contact, and a second backside source/drain contact. The first to third channel regions extend along a first direction and aligned with each other. The first gate structure is over the first channel region. The second gate structure is over the second channel region. The third gate structure is over the third channel region. The first to third gate structures and the isolation structure extend along a second direction different from the first direction and spaced apart from each other. The first source/drain epitaxial structure is between the first gate structure and the second gate structure in a top view. The second source/drain epitaxial structure is between the third gate structure and the isolation structure in the top view. The first backside source/drain contact is on a backside of the first source/drain epitaxial structure. The second backside source/drain contact is on a backside of the second source/drain epitaxial structure. A width of the second backside source/drain contact is greater than a width of the first backside source/drain contact.

In some embodiments of the present disclosure, a method includes forming a first isolation structure in a semiconductor substrate, wherein the first isolation structure surrounds a first channel region and a second channel region of the semiconductor substrate, wherein the first and second channel regions extend along a first direction and aligned with each other; forming a first dummy gate structure and a second dummy gate structure respectively over the first and second channel regions, wherein the first and second dummy gate structures extend along a second direction different from the first direction and spaced apart from each other; forming a source/drain epitaxial structure between the first and second channel regions; replacing the first dummy gate structure with a metal gate structure; replacing the second dummy gate structure with a second isolation structure; forming a backside source/drain contact on a backside of the source/drain epitaxial structure, wherein a center line of the backside source/drain contact extending along the second direction is misaligned with a center line of the source/drain epitaxial structure extending along the second direction in a first top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a channel region extending along a first direction;
a gate structure over the channel region;
an isolation structure, wherein the gate structure and the isolation structure extend along a second direction different from the first direction and spaced apart from each other;
a source/drain epitaxial structure between the gate structure and the isolation structure; and
a backside source/drain contact on a backside of the source/drain epitaxial structure, wherein a space between the backside source/drain contact and the isolation structure is less than a space between the backside source/drain contact and the gate structure in a first top view.

2. The IC structure of claim 1, further comprising:
a first inner spacer on a sidewall of the isolation structure; and
a second inner spacer on a sidewall of the gate structure, wherein the backside source/drain contact is in contact with the first inner spacer and spaced apart from the second inner spacer.

3. The IC structure of claim 1, further comprising:
a frontside source/drain contact on a frontside of the source/drain epitaxial structure, wherein a space between the frontside source/drain contact and the isolation structure is less than a space between the frontside source/drain contact and the gate structure in a second top view.

4. The IC structure of claim 3, further comprising:
a first gate spacer alongside the isolation structure; and
a second gate spacer alongside the gate structure, wherein the backside source/drain contact is in contact with the first gate spacer and spaced apart from the second gate spacer.

5. The IC structure of claim 3, further comprising:
a first front-side via on the frontside source/drain contact, wherein a space between the first front-side via and the isolation structure is less than a space between the first front-side via and the gate structure in the first top view.

6. The IC structure of claim 1, further comprising:
a dielectric liner on a sidewall of the backside source/drain contact.

7. The IC structure of claim 1, further comprising:
a dielectric isolation layer on a first portion of the backside of the source/drain epitaxial structure, wherein the backside source/drain contact is on a second portion of the backside of the source/drain epitaxial structure.

8. An integrated circuit (IC) structure, comprising:
a first channel region, a second channel region, and a third channel region extending along a first direction and aligned with each other;
a first gate structure over the first channel region;
a second gate structure over the second channel region;
a third gate structure over the third channel region;
an isolation structure, wherein the first to third gate structures and the isolation structure extend along a second direction different from the first direction and spaced apart from each other;
a first source/drain epitaxial structure between the first gate structure and the second gate structure in a top view;
a second source/drain epitaxial structure between the third gate structure and the isolation structure in the top view;
a first backside source/drain contact on a backside of the first source/drain epitaxial structure; and
a second backside source/drain contact on a backside of the second source/drain epitaxial structure, wherein a width of the second backside source/drain contact is greater than a width of the first backside source/drain contact.

9. The IC structure of claim 8, wherein a space between the second backside source/drain contact and the isolation structure is less than a space between the second backside source/drain contact and the third gate structure in the top view.

10. The IC structure of claim 8, wherein a space between the second backside source/drain contact and the third gate structure is substantially equal to a space between the first backside source/drain contact and the first gate structure in the top view.

11. The IC structure of claim 8, wherein the second backside source/drain contact is in contact with the isolation structure.

12. The IC structure of claim 8, wherein the second backside source/drain contact extends across the isolation structure.

13. The IC structure of claim 8, further comprising:
a first frontside source/drain contact on a frontside of the first source/drain epitaxial structure; and
a second frontside source/drain contact on a frontside of the second source/drain epitaxial structure, wherein a width of the second frontside source/drain contact is greater than a width of the first frontside source/drain contact.

14. The IC structure of claim 13, wherein a space between the second frontside source/drain contact and the isolation structure is less than a space between the second frontside source/drain contact and the third gate structure in the top view.

15. The IC structure of claim 13, wherein the second frontside source/drain contact is in contact with the isolation structure.

16. The IC structure of claim 13, wherein the second frontside source/drain contact extends across the isolation structure.

17. A method, comprising:
forming a first isolation structure in a semiconductor substrate, wherein the first isolation structure surrounds a first channel region and a second channel region of the semiconductor substrate, wherein the first and second channel regions extend along a first direction and aligned with each other;
forming a first dummy gate structure and a second dummy gate structure respectively over the first and second channel regions, wherein the first and second dummy gate structures extend along a second direction different from the first direction and spaced apart from each other;
forming a source/drain epitaxial structure between the first and second channel regions;
replacing the first dummy gate structure with a metal gate structure;
replacing the second dummy gate structure with a second isolation structure; and
forming a backside source/drain contact on a backside of the source/drain epitaxial structure, wherein a center line of the backside source/drain contact extending along the second direction is misaligned with a center line of the source/drain epitaxial structure extending along the second direction in a first top view.

18. The method of claim 17, further comprising:
forming a frontside source/drain contact on a frontside of the source/drain epitaxial structure, wherein a center line of the frontside source/drain contact extending along the second direction is misaligned with the center line of the source/drain epitaxial structure extending along the second direction in a second top view.

19. The method of claim 17, wherein forming the backside source/drain contact comprises:
etching a source/drain opening in the semiconductor substrate to expose the backside of the source/drain epitaxial structure; and
depositing a metal material into the source/drain opening.

20. The method of claim 19, further comprising:
forming a dielectric liner in the source/drain opening prior to depositing the metal material, wherein the dielectric liner exposes the backside of the source/drain epitaxial structure.
